(19) United States
(12) Patent Application Publication
(10) Pub. No.: US 2026/0090297 A1
(43) Pub. Date: Mar. 26, 2026

(54) METHOD OF MANUFACTURING SEMICONDUCTOR DEVICES

(71) Applicant: Infineon Technologies AG, Neubiberg (DE)

(72) Inventors: Hans-Joachim Schulze, Taufkirchen (DE); Werner Schustereder, Villach (AT); Daniel Schlögl, Villach (AT); Moriz Jelinek, Villach (AT); Francisco Javier Santos Rodriguez, St.Jakob im Rosental (AT); Denys Naumenko, Villach (AT)

(21) Appl. No.: 19/324,541

(22) Filed: Sep. 10, 2025

(30) Foreign Application Priority Data
Sep. 26, 2024 (DE) 102024209351.3

(51) Int. Cl. H01L 21/265; H01L 21/324

(52) U.S. Cl. CPC H10P 30/222; H10P 95/90

(57) ABSTRACT

A method of manufacturing semiconductor devices includes processing a semiconductor body at a first surface of the semiconductor body, including forming a wiring area over the first surface. Thereafter, the method further includes forming a field stop region in the semiconductor body. Forming the field stop region includes introducing implant ions including selenium into the semiconductor body through a second (opposite) surface of the semiconductor body by an ion implantation process. A main beam direction of the ion implantation process deviates from a main crystal direction of the semiconductor body, along which channeling of implant ions occurs, by at most 1 degree and a main beam incidence angle divergence is at most ±0.5 degree. Forming the field stop region further includes electrically activating at least part of the selenium by a laser annealing process.

### TECHNICAL FIELD

The present disclosure relates to a method of manufacturing semiconductor devices, in particular to a method of manufacturing semiconductor devices including forming a field stop region.

### BACKGROUND

Technology development of new generations of semiconductor devices, e.g. insulated gate field effect transistors (IGFETs) such as metal oxide semiconductor field effect transistors (MOSFETs) or insulated gate bipolar transistors (IGBTs) or diodes, aims at improving electrical device characteristics and reducing costs by shrinking device geometries. Although costs may be reduced by shrinking device geometries, a variety of tradeoffs and challenges have to be met when increasing device functionalities per unit area. For example, improving the electrical characteristics of field stop regions, e.g. with respect to reduced hot leakage currents and/or switch-off softness, may be challenging in view of process-related constraints. Such process-related constraints may be caused by thermal budget constraints due to the process sequence, e.g. thermal budget constraints for processing a rear side of a semiconductor body when front side processing has been completed or partly completed.

Thus, there is a need for improving a method for manufacturing semiconductor devices.

### SUMMARY

An example of the present disclosure relates to a method of manufacturing semiconductor devices. The method includes processing a semiconductor body at a first surface of the semiconductor body. Processing the semiconductor body includes forming a wiring area over the first surface. Thereafter, the method further includes forming a field stop region in the semiconductor body. Forming the field stop region includes introducing implant ions including selenium into the semiconductor body through a second surface of the semiconductor body by an ion implantation process. The second surface is opposite to the first surface. A main beam direction of the ion implantation process deviates from a main crystal direction of the semiconductor body, along which channeling of implant ions occurs, by at most 1 degree and a main beam incidence angle divergence is at most ±0.5 degree. Forming the field stop region further includes electrically activating at least part of the selenium by a laser annealing process.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A to 1C are cross-sectional views of a semiconductor body for illustrating process features of manufacturing semiconductor devices.

FIGS. 2 to 5 are cross-sectional views of a semiconductor body for illustrating process features that may be integrated into the method illustrated in FIGS. 1A to 1C.

FIG. 6 is a schematic top view for illustrating a pattern of applying a multi-pulse laser beam onto a surface of a semiconductor body.

### DETAILED DESCRIPTION

In the following detailed description, reference is made to the accompanying drawings, which form a part hereof and in which are shown by way of illustrations specific examples of methods of manufacturing semiconductor devices. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

The adjectives “first”, “second” may be used herein for distinguishing between features that are designated by the same term, e.g. first/second modifications or first/second separation area. The adjectives do not preclude the sequence of manufacture of the features. Thus, the first modifications may be formed before or after forming the second modifications.

An example of the present disclosure relates to a method of manufacturing semiconductor devices. The method includes processing a semiconductor body at a first surface of the semiconductor body. Processing the semiconductor body includes forming a wiring area over the first surface. Thereafter, the method further includes forming a field stop region in the semiconductor body. Forming the field stop region includes introducing implant ions including selenium into the semiconductor body through a second surface of the semiconductor body by an ion implantation process. The second surface is opposite to the first surface. A main beam direction of the ion implantation process deviates from a main crystal direction of the semiconductor body, along which channeling of implant ions occurs, by at most 1 degree and a main beam incidence angle divergence is at most ±0.5 degree. Forming the field stop region further includes electrically activating at least part of the selenium by a laser annealing process.

For example, the semiconductor devices may be dies in a semiconductor body. The semiconductor body may be based on various semiconductor materials, for example silicon (Si), silicon-on-insulator (SOI), silicon-sapphire (SOS), silicon-germanium, germanium, gallium arsenide, silicon carbide, gallium nitride, or other compound semiconductor materials. The semiconductor body may be based on a semiconductor base substrate, for example a semiconductor wafer and may include one or more epitaxial layers deposited thereon and/or may be back-thinned. For example, the semiconductor devices or dies may each be an integrated circuit, or a discrete semiconductor device. The integrated circuit or discrete semiconductor device may be or may include a power semiconductor device, e.g. a vertical power semiconductor device having a load current flow between a first surface and a second surface. The dies may be used in automotive, industrial power control, power management, sensing solutions and security in Internet of Things applications, for example. The dies may be or may include a power semiconductor diode, or a power semiconductor IGBT (insulated gate bipolar transistor), or a reverse conducting (RC) IGBT, or a power semiconductor transistor such as a power semiconductor IGFET (insulated gate field effect transistor, e.g. a metal oxide semiconductor field effect transistor). For example, a power semiconductor device in the dies may be configured to conduct currents of more than 1 A or more than 10 A or even more than 30 A. The semiconductor devices in the dies may be further configured to block voltages between load terminals, e.g. between emitter and collector of an IGBT, or between cathode and anode of a diode, or between drain and source of a MOSFET, in the range of several hundreds or up to several thousands of volts, e.g. 400 V, 650V, 1.2 kV, 1.7 kV, 3.3 kV, 4.5 kV, 5.5 kV, 6 kV, 6.5 kV, 10 kV.

Forming the wiring area may include forming one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be formed. Contact plug(s) or contact line(s) may be formed in openings in the interlayer dielectric structure to electrically connect parts, e.g. metal lines or contact areas, of different wiring levels to one another.

Processing the semiconductor body may further include, e.g. before forming the wiring area, at least one doping process for forming doped regions in the semiconductor body at the first surface. The at least one doping process may include an ion implantation process followed by a thermal activation of dopants, a diffusion process introducing the dopants into the semiconductor body from a dopant source (e.g. solid or gaseous diffusion source), an in-situ doping process when forming a semiconductor layer, e.g. by a layer deposition process, on a semiconductor base substrate such as a wafer. The exemplary doping processes may be combined in any way and may be repeated in any way, e.g. depending on a desired number and profile of the doped regions that are to be formed in the semiconductor substrate at the first surface. Exemplary doped regions are source and drain regions, or emitter and collector regions, anode and cathode regions, body region(s), body contact region(s), current spread region(s), shielding region(s) configured to shield a gate dielectric from high electric fields. The processes may also include trench etch processes. The trench etch processes may be used to form trenches such as gate electrode trenches, field electrode trenches, multi-electrode trenches (e.g. combining gate and field electrodes in one trench), trenches for edge termination structures, contact trenches for providing an electric contact to doped regions in the semiconductor substrate. The processes may also include forming insulating layer(s), conductive layer(s), or any combination thereof, in the trenches. Exemplary insulating or conductive layers include, inter alia, gate or field electrodes by doped semiconductor layers (e.g. doped polycrystalline silicon, or metal, or metal alloy), oxide layers (e.g. silicate glass, deposited SiO₂, thermal SiO₂), nitride layers (e.g., Si₃N₄), high-k dielectric layers, low-k dielectric layers, dielectric spacers, or any combination thereof.

The field stop region has a doping type, e.g. n-type or p-type, equal to the doping type of a drift region of the semiconductor device. The field stop region is arranged between the drift region and the second surface of the semiconductor body. The field stop region has a larger doping concentration than the drift region and plays a key role in the operational properties of the semiconductor devices. For example, thickness and concentration of the field stop region affect the switching and breakdown voltage characteristics of the semiconductor devices. Forming the field stop region includes a channeled ion implantation of implant ions including selenium for increasing a depth of the selenium doping profile.

The semiconductor body may have a crystal lattice suitable for channeling ions. Typically, in some crystal directions of single-crystalline materials open spaces extend straight into the crystal. The open spaces form channels through which ions travel with less interaction with the atoms of the crystal lattice than outside the channels. The channels steer to some degree the ions, wherein the ions entering such channels show a deceleration pattern that differs from the deceleration pattern for ions entering the semiconductor body outside the channels. The channel directions coincide with main crystal directions.

For example, the semiconductor body has a diamond cubic crystal lattice like silicon (Si). In case of a diamond cubic crystal lattice, the exposed process surface, e.g. the first surface, of the semiconductor body may coincide with a (100) crystal face, may be tilted to the {100} crystal face by at most ±2 degree or may be any other face suitable for channeling. Accordingly a <100>crystal direction, which is one of several main crystal directions of the semiconductor body along which channeling occurs, or any other suitable direction, runs perpendicular to the process surface and represents a direction denominated as main crystal direction.

The examples described herein for manufacturing semiconductor devices enable a number of technical benefits. For example, deep selenium profiles for field stop regions may be formed. A diffusion-component for extending the depth of the selenium profile may no longer be required when adjusting the thermal budget for the electrical activation of the selenium. This is due to the channeling implant of the selenium. Moreover, the deep selenium doping profiles may enable a reduction of the hot leakage currents and/or improvement of the switch-off softness.

For example, the laser annealing process may include sweeping a multi-pulse laser beam along a scan direction on the second surface of the semiconductor body. A pulse repetition frequency may be larger than 10 MHz. The multi-pulse beam laser may be further scanned along a second scan direction. This may allow for sweeping the multi-pulse laser beam line by line across the second surface of the semiconductor body. Applying the laser annealing process may allow for a deep electrical activation of the implanted dopants, e.g. selenium. For example the deep electrical activation may reach depths from the second surface of more than 1 μm, or more than 2 μm, or even more than 5 μm.

For example, the semiconductor devices may be power transistors or power diodes.

For example, the method may further include, after processing the semiconductor body at the first surface and before the laser annealing process, introducing implant ions including boron into the semiconductor body through the second surface of the semiconductor body by an ion implantation process. A penetration depth of the implant ions including boron is set smaller than a penetration depth of the implant ions including selenium. For example, the ion implantation process for introducing implant ions including boron into the semiconductor body may introduce the implant ions into the semiconductor body along a direction along which channeling does not occur, i.e. along a non-channeling direction. For example, the ion implantation process for introducing implant ions including boron into the semiconductor body may be a tilted ion implantation process. The laser annealing process may electrically activate not only at least part of the selenium of the field stop region but also at least part of the boron that may act as a collector region/rear-side emitter region of an IGBT, for example.

In other words, the laser annealing process for electrically activating at least part of the selenium is concurrently used for electrically activating at least part of the boron.

For example, the method may further include, after processing the semiconductor body at the first surface and before the laser annealing process, introducing protons into the semiconductor body through the second surface of the semiconductor body by an ion implantation process. This may allow for setting a doping concentration profile of the field stop region by hydrogen-related donors and selenium. The laser annealing process for electrically activating at least part of the selenium may be concurrently used for electrically activating at least part of the protons (hydrogen related donors). In some examples, the protons may be electrically activated by a furnace process, for example.

For example, the method may further include, after processing the semiconductor body at the first surface, introducing implant ions including phosphorus ions into the semiconductor body through the second surface of the semiconductor body by an ion implantation process. For example, a penetration depth of the implant ions including phosphorus may be set smaller than a penetration depth of the implant ions including selenium.

For example, the laser annealing process for electrically activating at least part of the selenium may be concurrently used for electrically activating at least part of the phosphorus.

For example, the method may further include, after the laser annealing process for electrically activating at least part of the selenium, electrically activating at least part of the phosphorous by a second laser annealing process. A combination of a laser annealing process in the sub-melt mode regime for electrically activating at least part of the selenium and a laser annealing process in the melt mode regime for electrically activating at least part of the phosphorus may be applied, for example.

For example, the method may further include, before forming the field stop region and after processing the semiconductor body at the first surface, at least partially removing a dielectric layer from the second surface of the semiconductor body. For example, an oxide may be removed before introducing implant ions including selenium into the semiconductor body through the second surface of the semiconductor body by an ion implantation process. The oxide may be removed by hydrofluoric, HF acid and/or HF gas. This may allow for increasing a penetration depth of the implant ions including selenium into the semiconductor body.

For example, the laser annealing process for electrically activating the selenium may be a non-melt laser annealing process.

For example, the method may further include forming an ion implantation mask having mask openings for introducing the implant ions including selenium into the semiconductor body through the mask openings.

For example, the semiconductor body may be a wafer including a plurality of dies, and the multi-pulse laser beam of the laser annealing process for electrically activating at least part of the selenium may be applied to only a part of a surface area of each of the plurality of dies. This may allow for adjusting electrical characteristics depending on a lateral position in the die or semiconductor device. For example, this may allow for setting the electrical characteristics in an active area of the semiconductor device different from the electrical characteristics at or around the chip or die edge.

For example, the method may further include electrically activating at least part of the selenium in another part of the surface area of each of the plurality of dies by a further or second laser annealing process. This may allow for realizing selenium doping profiles of different depths, e.g. in alignment to structures at the first surface of the die or semiconductor body.

For example, the ion implantation process for introducing implant ions including selenium into the semiconductor body may include an ion implantation energy in a range from 50 keV to 500 keV. The ion implantation process for introducing implant ions including selenium into the semiconductor body may further include and an ion implantation dose in a range from 1×10¹² cm⁻² to 1×10¹⁴ cm⁻².

For example, the multi-pulse laser beam of the laser annealing process for electrically activating the selenium may have a beam size in a range from 100 μm² to 0.1 mm².

For example, a sweeping velocity of the multi-pulse laser beam along the scan direction on the second surface of the semiconductor body may be in a range from 10 m/s to 100 m/s.

For example, a pulse length of a pulse of the multi-pulse laser beam may be in a range from 0.5 ns to 10 ns. The multi-pulse laser beam parameters described herein may contribute to a deep electrical activation of the selenium introduced by the channeling ion implantation, for example.

For example, sweeping of the multi-pulse laser beam along the scan direction may be carried out line by line, wherein neighboring lines are offset to each other along a direction perpendicular to the scan direction by less than a dimension of a beam size of the multi-pulse laser beam along the direction perpendicular to the scan direction. This may allow for homogeneously electrically activating the selenium along the direction perpendicular to the scan direction.

For example, sweeping of the multi-pulse laser beam along the scan direction may be carried out line by line, wherein neighboring lines are offset to each other along a direction perpendicular to the scan direction by more than a dimension of a beam size of the multi-pulse laser beam along the direction perpendicular to the scan direction. This may allow for varying a degree of electrical activation of the selenium along the direction perpendicular to the scan direction. For example, alternating low/high doped regions may be formed tuning a backside or rear side emitter efficiency of an IGBT.

For example, the processes of implanting the dopant ions including selenium and activation by the laser annealing process can be carried out using a wafer with or without a carrier attached to the wafer. For example, in case thin wafers or back-thinned wafers, the carrier may be used.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

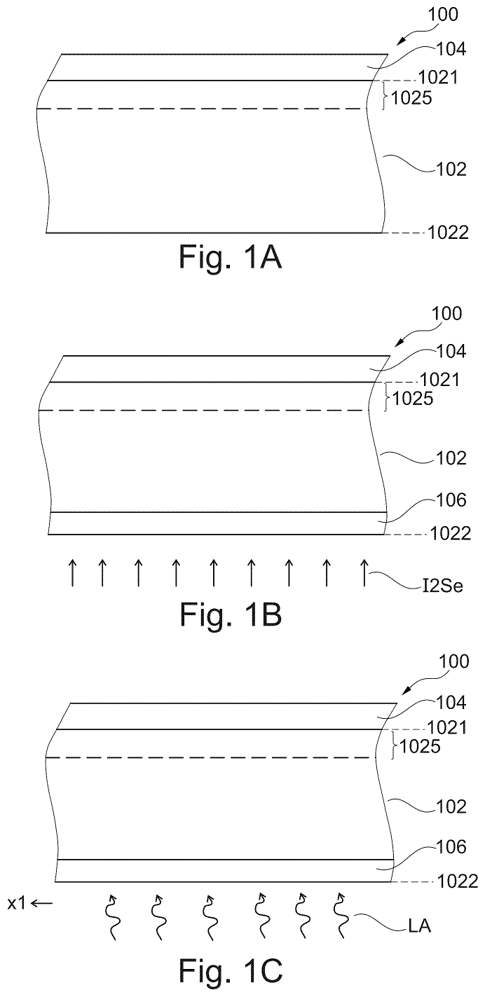

FIGS. 1A to 1C are schematic cross-sectional views for illustrating exemplary process features of a method of manufacturing semiconductor devices.

Referring to the schematic cross-sectional view of FIG. 1A, a semiconductor body 102 is processed at a first surface 1021 of the semiconductor body 102. Processing the semiconductor body 102 includes forming semiconductor device elements in a portion 1025 of the semiconductor body 102 that adjoins the first surface 102. Processing the semiconductor body 102 further includes forming a wiring area 104 over the first surface 1021.

Referring to the schematic cross-sectional view of FIG. 1B, after carrying out the process features illustrated in FIG. 1A, a field stop region 106 is formed in the semiconductor body. Forming the field stop region 106 includes introducing implant ions including selenium into the semiconductor body 102 through a second surface 1022 of the semiconductor body 102 by an ion implantation process I2Se. The second surface 1022 is opposite to the first surface 1021. A main beam direction of the ion implantation process I2Se deviates from a main crystal direction of the semiconductor body 102, along which channeling of implant ions occurs, by at most 1 degree and a main beam incidence angle divergence is at most ±0.5 degree.

Referring to the schematic cross-sectional view of FIG. 1C, at least part of the selenium is electrically activated by a laser annealing process LA.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts,-functions,-processes,-operations or -steps, respectively. Such sub acts may be included and part of the disclosure of this single act unless explicitly excluded.

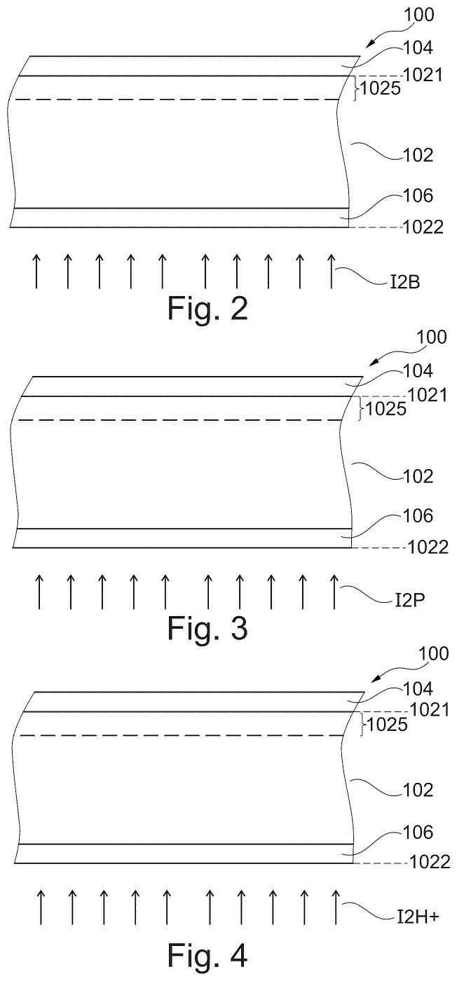

Referring to the schematic cross-sectional view of FIG. 2, after processing the semiconductor body 102 at the first surface 1021 and before the laser annealing process LA, i.e. after the process features illustrated in FIG. 1A and before the process features illustrated in FIG. 1C, implant ions including boron are introduced into the semiconductor body 102 through the second surface 1022 of the semiconductor body 102 by an ion implantation process I2B. The laser annealing process LA described with reference to FIG. 1C may be concurrently used for electrically activating at least part of the boron.

Referring to the schematic cross-sectional view of FIG. 3, after processing the semiconductor body 102 at the first surface 1021 and before the laser annealing process LA, i.e. after the process features illustrated in FIG. 1A and before the process features illustrated in FIG. 1C, implant ions including phosphorus are introduced into the semiconductor body 102 through the second surface 1022 of the semiconductor body 102 by an ion implantation process I2P. The laser annealing process LA described with reference to FIG. 1C may be concurrently used for electrically activating at least part of the phosphorus.

Referring to the schematic cross-sectional view of FIG. 4, after processing the semiconductor body 102 at the first surface 1021 and before the laser annealing process LA, i.e. after the process features illustrated in FIG. 1A and before the process features illustrated in FIG. 1C, implant ions including protons are introduced into the semiconductor body 102 through the second surface 1022 of the semiconductor body 102 by an ion implantation process I2H+. The laser annealing process LA described with reference to FIG. 1C may be concurrently used for electrically activating at least part of the protons as hydrogen-related donors.

As is illustrated in the schematic cross-sectional view of FIG. 5, a second laser annealing process LA2 and/or third laser annealing process LA3 is applied to the second surface 1022. For example, the second laser anneal process LA2 may be applied after the laser anneal process LA illustrated in FIG. 1C, e.g. in case boron and/or phosphorus and/or protons are not implanted between the process features as illustrated in FIG. 1A and FIG. 1C, but after the process feature illustrated in FIG. 1C. In this case, the second laser anneal process LA2 at least partially electrically activates the boron and/or phosphorus and/or protons as hydrogen-related donors. Likewise, the second laser anneal process LA2 may be applied after the process features illustrated in FIG. 1A and before the process features illustrated in FIG. 1B, e.g. in case boron and/or phosphorus and/or protons are implanted before the process features as illustrated in FIG. 1B. In this case, the second laser anneal process LA2 at least partially electrically activates the boron and/or phosphorus and/or protons as hydrogen-related donors before the channeling implant of selenium is carried out. The third layer anneal process LA3 may be applied to surface areas at the second surface 1022 other than surface areas where the laser anneal process LA has been applied, for example.

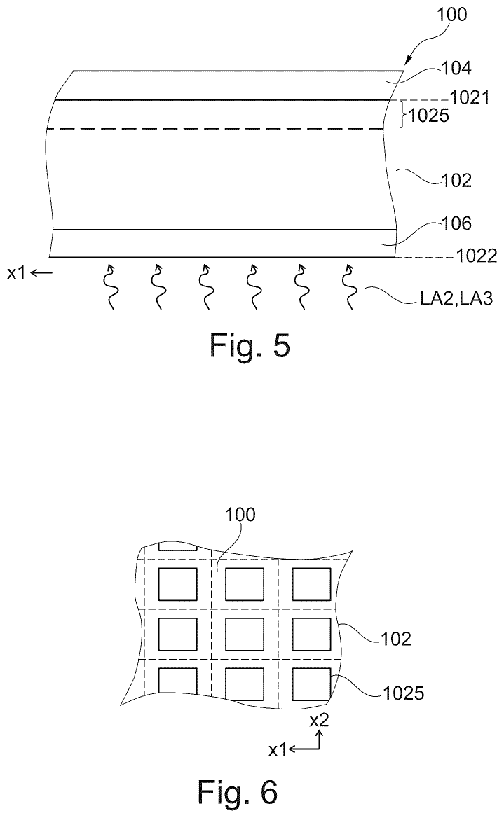

The schematic top view of FIG. 6 illustrates one example of applying the multi-pulse laser beam of the laser annealing process LA for electrically activating at least part of the selenium to only a part 1025 of a surface area of each of the plurality of dies or semiconductor devices 100. The pattern illustrated in FIG. 6 may be formed by sweeping of the multi-pulse laser beam along the scan direction x1 line by line, and i) interrupting sweeping of the multi-pulse laser beam along the scan direction x1, and ii) introducing an offset between neighboring lines along a direction x2 perpendicular to the scan direction x1 by more than a dimension of a beam size of the multi-pulse laser beam along the direction x2. For example, the third laser anneal process LA3 may be applied to a part of a surface area outside of the part 1025. The pattern of applying the multi-pulse laser beam of the laser annealing process LA for electrically activating at least part of the selenium may deviate from the exemplary pattern of FIG. 6 and may be adapted as desired.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing semiconductor devices, the method comprising:
processing a semiconductor body at a first surface of the semiconductor body, wherein the processing includes forming a wiring area over the first surface; and
after the processing, forming a field stop region in the semiconductor body,
wherein forming the field stop region includes:
introducing implant ions including selenium into the semiconductor body through a second surface of the semiconductor body by an ion implantation process, the second surface being opposite to the first surface, wherein a main beam direction of the ion implantation process deviates from a main crystal direction of the semiconductor body, along which channeling of implant ions occurs, by at most 1 degree and a main beam incidence angle divergence is at most ±0.5 degree; and
electrically activating at least part of the selenium by a laser annealing process.

2. The method of claim 1, wherein the laser annealing process includes sweeping a multi-pulse laser beam along a scan direction on the second surface of the semiconductor body, with a pulse repetition frequency larger than 10 MHz.

3. The method of claim 1, wherein the semiconductor devices are power transistors or power diodes.

4. The method of claim 1, further comprising:
after the processing and before the laser annealing process, introducing implant ions including boron into the semiconductor body through the second surface of the semiconductor body by an ion implantation process, wherein a penetration depth of the implant ions including boron is set smaller than a penetration depth of the implant ions including selenium.

5. The method of claim 4, wherein the laser annealing process for electrically activating at least part of the selenium is concurrently used for electrically activating at least part of the boron.

6. The method of claim 5, further comprising:
after the processing and before the laser annealing process, introducing protons into the semiconductor body through the second surface by an ion implantation process.

7. The method of claim 6, further comprising:
after the processing, introducing implant ions including phosphorus ions into the semiconductor body through the second surface by an ion implantation process.

8. The method of claim 7, wherein the laser annealing process for electrically activating the selenium is concurrently used for electrically activating at least part of the phosphorus.

9. The method of claim 7, further comprising:
after the laser annealing process for electrically activating at least part of the selenium, electrically activating at least part of the phosphorous by a second laser annealing process.

10. The method of claim 1, further comprising:
before forming the field stop region and after the processing, at least partially removing a dielectric layer from the second surface of the semiconductor body.

11. The method of claim 1, wherein the laser annealing process for electrically activating at least part of the selenium is a non-melt laser annealing process.

12. The method of claim 1, further comprising:
forming an ion implantation mask having a plurality of mask openings for introducing the implant ions including selenium into the semiconductor body through the mask openings.

13. The method of claim 1, wherein the semiconductor body is a wafer including a plurality of dies, and wherein a multi-pulse laser beam of the laser annealing process for electrically activating at least part of the selenium is applied to only a part of a surface area of each of the plurality of dies.

14. The method of claim 13, further comprising:
electrically activating at least part of the selenium in another part of the surface area of each of the plurality of dies by a third laser annealing process.

15. The method of claim 1, wherein the ion implantation process for introducing implant ions including selenium into the semiconductor body includes an ion implantation energy in a range from 50 keV to 500 keV and an ion implantation dose in a range from 1×10¹² cm⁻² to 1×10¹⁴ cm⁻².

16. The method of claim 1, wherein a multi-pulse laser beam of the laser annealing process for electrically activating the selenium has a beam size in a range from 100 μm² to 0.1 mm².

17. The method of claim 1, wherein a sweeping velocity of a multi-pulse laser beam of the laser annealing process for electrically activating the selenium along a scan direction on the second surface of the semiconductor body is in a range from 10 m/s to 100 m/s.

18. The method of claim 1, wherein a pulse length of a pulse of a multi-pulse laser beam of the laser annealing process for electrically activating the selenium is in a range from 0.5 ns to 10 ns.

19. The method of claim 1, wherein the ion implantation process comprises sweeping a multi-pulse laser beam along a scan direction line by line, and wherein neighboring lines are offset to each other along a direction perpendicular to the scan direction by less than a dimension of a beam size of the multi-pulse laser beam along the direction perpendicular to the scan direction.

20. The method of claim 1, wherein the ion implantation process comprises sweeping a multi-pulse laser beam along a scan direction line by line, and wherein neighboring lines are offset to each other along a direction perpendicular to the scan direction by more than a dimension of a beam size of the multi-pulse laser beam along the direction perpendicular to the scan direction.
